(19) United States
(12) Patent Application Publication
(10) Pub. No.: US 2026/0243933 A1
(43) Pub. Date: Aug. 20, 2026

(54) OPTICAL FILTER ARRANGEMENT

(71) Applicant: METAHELIOS LIMITED, Glasgow (GB)

(72) Inventors: Yash Diptesh SHAH, Glasgow (GB); Charles ALTUZARRA, Glasgow (GB)

(21) Appl. No.: 19/161,137

(22) PCT Filed: Feb. 28, 2024
(86) PCT No.: PCT/GB2024/050538

§ 371 Date: Aug. 29, 2025

(30) Foreign Application Priority Data
Mar. 1, 2023 (GB) 2303029.9

(51) Int. Cl. G02B 5/20; H04N 23/55

(52) U.S. Cl. CPC G02B 5/201; H04N 23/55; G02B 2207/101

(57) ABSTRACT

An optical filter arrangement for use with an image sensor, the arrangement including at least one first filter element including a plurality of first nanostructures, and at least one second filter element including a plurality of second nanostructures, wherein the plurality of first nanostructures is configured such that the at least one first filter element includes a first transmission wavelength and the plurality of second nanostructures is configured such that the at least one second filter element includes a second transmission wavelength that is different from the first transmission wavelength.

### FIELD

The present disclosure relates to an optical filter arrangement, an imaging system and associated methods.

### BACKGROUND

Infra-red cameras may have a wide range of applications. Such applications may include but not be limited to the detection of atmospheric gases, including greenhouse gases, such as carbon dioxide, methane, nitrous oxide or the like, the differentiation of ice from water, defects in plastic materials, fissures in vehicle or the like. However, an array of filters may be necessary in order to be able to differentiate selected image data from other image data and/or to improve a spectral resolution of selected image data.

For example, Fabry-Perot cavity filter arrays may be used in a wavelength range of 1100 nm to 1600 nm. The manufacture of such filter arrays may involve a number of lithographic processes, which may result increased manufacture costs and/or times. As these filter arrays are based on constructive interference of light, they transmit multiples of a selected wavelength. For example, a Fabry-Perot cavity filter array configured to transmit light having a wavelength of about 1600 nm may also transmit light having a wavelength of 800 nm and 400 nm, which may be undesirable. As such, there is a need for an improved infra-red filter array.

This background serves only to set a scene to allow a person skilled in the art to better appreciate the following description. Therefore, none of the above discussion should necessarily be taken as an acknowledgement that that discussion is part of the state of the art or is common general knowledge. One or more aspects/embodiments of the disclosure may or may not address one or more of the background issues.

### SUMMARY

According to a first aspect of the present disclosure, there is provided an optical filter arrangement for use with an image sensor, the arrangement comprising at least one first filter element comprising a plurality of first nanostructures, and at least one second filter element comprising a plurality of second nanostructures, wherein the plurality of first nanostructures is configured such that the at least one first filter element comprises a first transmission wavelength and the plurality of second nanostructures is configured such that the at least one second filter element comprises a second transmission wavelength that is different from the first transmission wavelength.

By configuring the plurality of second nanostructures such that the at least second filter element comprises the second transmission wavelength that is different from the first transmission wavelength, the arrangement may allow for the parallel acquisition of image data associated with at least two different wavelengths, e.g. using a single imaging sensor.

The plurality of first nanostructures and the plurality of second nanostructures may allow for each of the at least one first filter element and the at least one second filter element to be manufactured with a size or dimension corresponding, e.g. substantially corresponding, to a size or dimension of a pixel of an image sensor.

Additionally or alternatively, by providing the at least one first filter element with the plurality of first nanostructures and the at least one second filter element with the plurality of second nanostructures, the detection of multiples of a transmission wavelength may be prevented. The at least one first filter element and the at least one second filter element may be configured to allow for resonant coupling of surface plasmon polaritons (SPP) on a respective surface of the at least one first filter element and the at least one second filter element. Light or radiation incident on the at least one first filter element and the at least one second filter element may lead to extraordinary optical transmission (EOT).

The first and/or second transmission wavelengths may be between about 0.8 μm and about 7 μm. This may allow for the detection of atmospheric gases, such as greenhouse gases. Additionally or alternatively, this may allow for the detection of water in soil, the detection of human skin, the detection of fissures or defects in materials, such as plastics materials, the differentiation of ice from water or the like. Expressed differently, the arrangement may allow for the detection of any material that exhibits an optical spectrum in the wavelength range of about 0.8 μm and about 7 μm.

The at least one first filter element and the at least one second filter element may be arranged to form an array of filter elements. This may facilitate use of the arrangement with an image sensor.

At least one or each of the at least one first element and the at least one second filter element may comprise a layer of metal material. The plurality of first nanostructures and the plurality of second nanostructures may be formed in the layer of metal material of the at least one or each of the at least one first filter element and the at least one second filter element. Alternatively, at least one or each of the at least one first filter element and the at least one second filter element may comprise a layer of glass material.

At least one or each of the at least one first element and the at least one second filter element may comprise a layer of dielectric material. The layer of dielectric material may be arranged on the layer of metal material of the at least one or each of the at least one first filter element and the at least one second filter element. Alternatively, the layer of dielectric material may be arranged on the layer of glass material of the at least one first filter element and the at least one second filter element.

The layer of metal material may comprise at least one of: gold, silver, chromium, copper and aluminium. The layer of glass material may comprise a chalcogenide glass material, such as germanium-antimony-tellurium (GST) or the like. The layer of dielectric material may comprise an oxide material, such as silicon dioxide, and/or a silicon nitride material, such as a silicon nitride material. The layer of dielectric material may improve a transmission of the at least one or each of the at least one first filter element and the at least one second filter element.

At least one or each of the plurality of first and second of nanostructures may comprise a plurality of holes, a plurality of slits, a plurality of grooves and/or a plurality of protrusions. The plurality of first and/or second nanostructures may be arranged in a periodic arrangement.

The first transmission wavelength may depend on a dimension of each of the plurality of first nanostructures and/or a periodicity of the plurality of first nanostructures. The second transmission wavelength may depend on a dimension of each of the plurality of second nanostructures and/or a periodicity of the plurality of second nanostructures. The dimension of each of the plurality of second nanostructures and/or the periodicity of the plurality of second nanostructures may be different from the dimension of each of the plurality of first nanostructures and/or the periodicity of the plurality of first nanostructures. The first transmission wavelength may be varied or changed by varying or changing the dimension of each of the plurality of first nanostructures and/or the periodicity of the plurality of first nanostructures. The second transmission wavelength may be varied or changed by varying or changing the dimension of each of the plurality of second nanostructures and/or the periodicity of the plurality of second nanostructures. The at least one first filter element and the at least one second filter element may each comprise or define an electromagnetic metasurface.

The arrangement may comprise at least one window or opening. The at least one window or opening may be arranged adjacent at least one of: the at least one first filter element and the at least one second filter element. The at least one window or opening may allow for the acquisition of unfiltered image data at the same time as image data that is filtered by the at least one first filter element and/or the at least one second filter element.

The at least one first filter element, the at least one second filter element and/or the at least one window or opening may be alternately arranged. For example, the at least one first filter element, the at least one second filter element and/or the at least one window or opening may be arranged to define a chequered arrangement. Alternatively or additionally, the at least one first filter element, the at least one second filter element and/or the at least one window may be arranged to form a mosaic arrangement, such as a mosaic quad arrangement, a random arrangement or semi random arrangement.

The arrangement may comprise at least one further filter element. The further element may comprise a plurality of further nanostructures. The plurality of further nanostructures may be configured such that the at least one further filter element comprises a further transmission wavelength that is different from the first and second transmission wavelengths.

According to a second aspect of the present disclosure, there is provided a method of generating an image acquired by an imaging system, the imaging system comprising an image sensor, the image sensor comprising an array of pixels, and an optical filter arrangement according to the first aspect, wherein the at least one first filter element is associated with at least one first pixel of the array of pixels and the at least one second filter element is associated with at least one second pixel of the array of pixels, the method comprising receiving data representative of a first signal detected by the at least one first pixel, receiving data representative of a second signal detected by the at least one second pixel, selecting at least one of the first signal and the second signal to generate the image and generating the image using the selected at least one of the first signal and the second signal.

The method may allow for so-called “post-processing” of the array of pixels of the image sensor. For example, an image based on the at least one first pixel and/or the at least one second pixel, which are associated with the at least one first filter element and/or the at least one second filter element, respectively, may be generated.

The first and second signals may be received at the same time or sequentially.

The method may comprise displaying the image. The image may comprise a filtered image.

The at least one window or opening may be associated with at least one third pixel of the array of pixels. Alternatively or additionally, the array of pixels may comprise another pixel. The other pixel may be configured to detect unfiltered light or radiation. The method may comprise receiving data representative of a third signal detected by the at least one third pixel or the other pixel. The method may comprise selecting the third signal, e.g. to generate an unfiltered image. The method may comprise generating the unfiltered image, e.g. using the third signal. The method May comprise displaying the unfiltered image.

According to a third aspect of the present disclosure, there is provided an imaging system comprising an image sensor, the image sensor comprising an array of pixels, and an optical filter arrangement according to the first aspect, wherein the at least one first filter element is associated with at least one first pixel of the array of pixels and the at least one second filter element is associated with at least one second pixel of the array of pixels.

The arrangement and/or system may allow for multispectral imaging, e.g. using a single imaging sensor. For example, the arrangement and/or system may reduce a number of imaging sensors required for multispectral imaging. Some multispectral imaging systems may comprise multiple imaging sensors, wherein each of the multiple imaging sensors has a respective filter. Each of the multiple imaging sensors may consume power and/or generate electrical noise. As such, a power consumption and/or a generation of electrical noise in the imaging system comprising the arrangement may be reduced compared to multispectral imaging systems comprising the multiple imaging sensors. This in turn may lead to an improved signal to noise ratio. The arrangement may allow for the imaging system to more compact compared to multispectral imaging systems comprising the multiple imaging sensors. Additionally or alternatively, the use of an optical diffraction element, such as a prism, grating or the like, and associated devices, such as one or more actuators for moving the diffraction element, may be avoided. This may facilitate the use of the imaging system in devices, systems or apparatuses with limited space, such as vehicles, satellites or the like.

The arrangement may be arranged relative to the array of pixels such that the at least one first filter element is associated with the at least one first pixel of the array of pixels and the at least one second filter element is associated with the at least one second pixel of the array of pixels.

The arrangement may be arranged relative to the array of pixels, e.g. such that light or radiation detected by the image sensor passes through the at least one first filter element and/or the at least one second filter element before being incident on the at least one first pixel of the array of pixels and/or the at least one second pixel of the array of pixels, respectively.

The at least one window or opening may be associated with at least one third pixel of the array of pixels. The arrangement may be arranged relative to the array of pixels such that the at least one window or opening is associated with the at least one third pixel of the array of pixels.

The system comprises a processing device configured to carry out the method according to the second aspect.

According to a fourth aspect of the present disclosure, there is provided a computer program comprising instructions which, when the program is executed by a processing device, cause the processing device to carry out the method according to the second aspect.

According to a fifth aspect of the present disclosure, there is provided a method of manufacturing an optical filter arrangement for use with an image sensor, the method comprising forming at least one first filter element comprising a plurality of first nanostructures, and forming at least one second filter element comprising a plurality of second nanostructures, wherein the plurality of first nanostructures is configured such that the at least one first filter element comprises a first transmission wavelength and the plurality of second nanostructures is configured such that the at least one second filter element comprises a second transmission wavelength that is different from the first transmission wavelength.

According to a sixth aspect of the present disclosure, there is provided a method of manufacturing an imaging system, the method comprising providing an image sensor comprising an array of pixels, and providing an optical filter arrangement according to the first aspect, and mounting the optical filter arrangement to the image sensor such that the at least one first filter element is associated with at least one first pixel of the array of pixels and the at least one second filter element is associated with at least one second pixel of the array of pixels.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

Some preferred embodiments of the disclosure will now be described by way of example only and with reference to the accompanying drawings, in which:

FIG. 1 depicts a schematic view of an exemplary imaging system according to an embodiment, the imaging system comprising an optical filter arrangement and an image sensor;

FIG. 2 depicts a cross-sectional view of the imaging system of FIG. 1;

FIG. 3 depicts a schematic view of an exemplary optical filter arrangement for use in the imaging system of FIG. 1;

FIG. 4 depicts a schematic view of another exemplary optical filter arrangement for use in the imaging system shown in FIG. 1;

FIG. 5 depicts a schematic view of another exemplary optical filter arrangement for use in the imaging system shown in FIG. 1;

FIG. 6 depicts a schematic view of exemplary first and second filter elements for use in the optical filter arrangement of any one of FIGS. 1 to 5, the first filter element comprising first nanostructures and the second filter element comprising second nanostructures;

FIG. 7 depicts a schematic view of a unit cell of the first and second nanostructures of FIG. 6;

FIG. 8 depicts simulated transmission spectra for three exemplary filter elements, one or more of which may be may be used in the optical filter arrangement of any one of FIGS. 1 to 5;

FIG. 9 depicts a flow chart illustrating in overview a method of generating an image acquired by an imaging system according to an embodiment;

FIG. 10A schematically depicts an exemplary matrix or array generated for an image frame acquired by the image sensor of FIG. 1;

FIG. 10B depicts an enlarged portion of the matrix or array of FIG. 10A;

FIG. 11A schematically depicts an exemplary further matrix or array that has been generated using a plurality of first signals of the matrix or array of FIG. 10A;

FIG. 11B schematically depicts an exemplary further matrix or array that has been generated using a plurality of second signals of the matrix or array of FIG. 10A;

FIG. 12 depicts a flow chart illustrating in overview a method of manufacturing an optical filter arrangement according to an embodiment;

FIG. 13 depicts a schematic cross-sectional view of a filter element for use in the optical filter arrangement of any one of FIGS. 1 to 5; and

FIG. 14 depicts a flow chart illustrating in overview a method of manufacturing an imaging system according to an embodiment.

### DETAILED DESCRIPTION

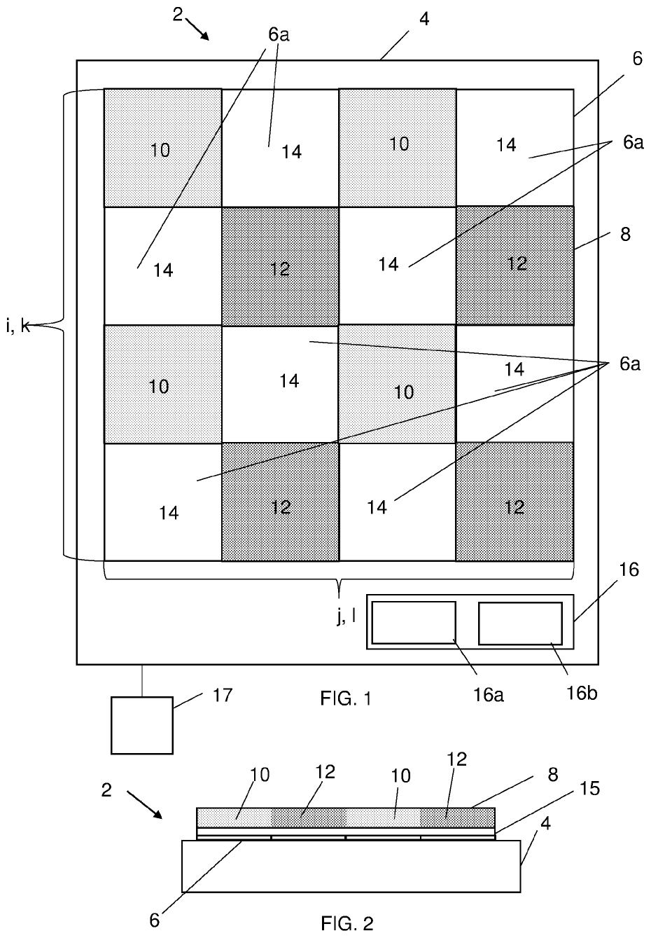

FIG. 1 shows a schematic view of an exemplary imaging system 2 according to an embodiment. The system 2 comprises an image sensor 4 comprising an array of pixels 6. Only some pixels 6a of the array of pixels are shown in FIG. 1. The array of pixels 6 may comprise j columns of pixels and i rows of pixels. In the embodiment shown in FIG. 1, j and i equal four. However, it will be appreciated that in other embodiments, the array of pixels may comprise more or less than four columns of pixels and/or four rows of pixels. For example, the array of pixels may comprise 1280 columns of pixels and 1024 rows of pixels or vice versa, or other numbers of rows and columns. The number of rows and columns of the array of pixels 6 may determine a size and/or resolution of the array of pixels 6. The image sensor 4 may be provided in the form of a single-photon avalanche diode (SPAD) array. However, it will be appreciated that in other embodiments, another image sensor, such as a charge-coupled device (CCD), complementary metal-oxide-semiconductor CMOS sensor, such as a CMOS sensor comprising a III-V compound semiconductor material and/or a II-VI compound semiconductor material, an active-pixel sensor or the like, may be used.

The system 2 comprises an optical filter arrangement 8. The arrangement 8 comprises at least one first filter element 10 and at least one second filter element 12. In the embodiment shown in FIG. 1, the arrangement 8 comprises four first filter elements 10 and four second filter elements 12. Each of the first filter elements 10 comprises a first transmission wavelength. Each of the second filter elements 12 comprises a second transmission wavelength that is different from the first transmission wavelength. It will be appreciated that in other embodiments, the arrangement may comprise more or less than four first filter elements and/or more or less than four second filter elements. Additionally or alternatively, the arrangement may comprise at least one further filter element, the further element having a further transmission wavelength that is different from the first and second transmission wavelengths.

As can be seen from FIG. 1, the first and second filter elements 10, 12 are arranged to form an array of filter elements. This may facilitate use of the arrangement with an image sensor. In the embodiment shown in FIG. 1, the array of filter elements comprises k rows and I columns, whereby k=1 to i and l=1 to j. In other words, the array of filter elements may comprise the same or less than a number of columns and/or rows of the array of pixels 6. The number of rows and columns of the array of filter elements may determine a size and/or resolution of the array of filter elements.

The arrangement 8 may comprise at least one window 14. In the embodiment shown in FIG. 1, the arrangement 8 comprises a plurality of windows 14, eight of which are shown. The windows 14 may also be referred to as openings or blank spaces. It will be appreciated that in other embodiments, the arrangement may comprise more or less than eight windows. Some of the pixels 6a of the array of pixels 6 are visible through the windows 14.

In the exemplary arrangement 8 shown in FIG. 1, each first filter element 10 is arranged adjacent to a window 14 and each second filter element 12 is arranged adjacent to another window 14. However, it will be appreciated that in other embodiments, the windows, first and second filter elements may be differently arranged and/or the arrangement may comprise no windows.

Each of the first and second filter elements 10, 12 may be associated with at respective pixel of the array of pixels 6. For example, each of the first filter elements 10 is associated with a respective first pixel of the array of pixels 6. The arrangement 8 may be arranged relative to the array of pixels 6 such that each first filter element 10 covers each respective first pixel. For example, the arrangement 8 may be arranged relative to the array of pixels 6 such that light or radiation detected by the image sensor 4 passes through each first filter element 10 prior to being incident on each respective first pixel.

Each of the of the second filter elements 12 is associated with a respective second pixel of the array of pixels 6. The arrangement 8 may be arranged relative to the array of pixels 6 such that each second filter element 12 covers each respective second pixel. For example, the arrangement 8 may be arranged relative to the array of pixels 6 such that light or radiation detected by the image sensor 4 passes through the second filter element 12 prior to being incident on each respective second pixel.

Each of the windows 14 is associated with a respective third pixel of the array of pixels 6. The third pixels are indicated in FIG. 1 by reference numeral 6a. Each window 14 may be arranged such that unfiltered light or radiation is detected by each respective third pixel.

In the embodiment shown in FIG. 1, the system 2 also comprise a processing device 16. The processing device 16 may include one or more processors 16a, such as a field programmable gate array (FPGA), a digital signal processor (DSP), an application specific integrated circuit (ASIC) and/or the like. The processing device 16 may include a storage medium 16b, such as non-transitory computer-readable storage medium. The storage medium 16b may comprise a volatile memory, e.g. random access memory (RAM), non-volatile memory, e.g. read-only memory (ROM) and/or electrically-erasable programmable ROM (EEPROM), or the like. The system 2 may be comprise a display screen 17 for displaying one or more images obtained by image sensor 4. The display screen 17 may be provided in the form of a CRT (cathode ray tube), plasma, LED (light emitting diode) or LCD (liquid crystal display) screen or monitor. It will be appreciated that in other embodiments, the display may be separately provided from the system.

FIG. 2 shows a cross-sectional view of the system 2 shown in FIG. 1. The arrangement 8 may be arranged relative to the image sensor 4 such that each of the first filter element 10, second filter element 12 and the windows 14 are associated with and/or aligned relative to the first, second and third pixels, respectively. The arrangement 8 may be arranged relative to the image sensor 4 such that light or radiation detected by the image sensor passes through the arrangement 8 prior to being incident on the array of pixels 6. The arrangement 8 may be mounted to the image sensor 4 using a layer of adhesive 15, such as a layer of a transparent adhesive. The layer of adhesive 15 may comprise a thickness of about 5 μm. However, it will be appreciated that in other embodiments, the arrangement may be differently mounted to the image sensor.

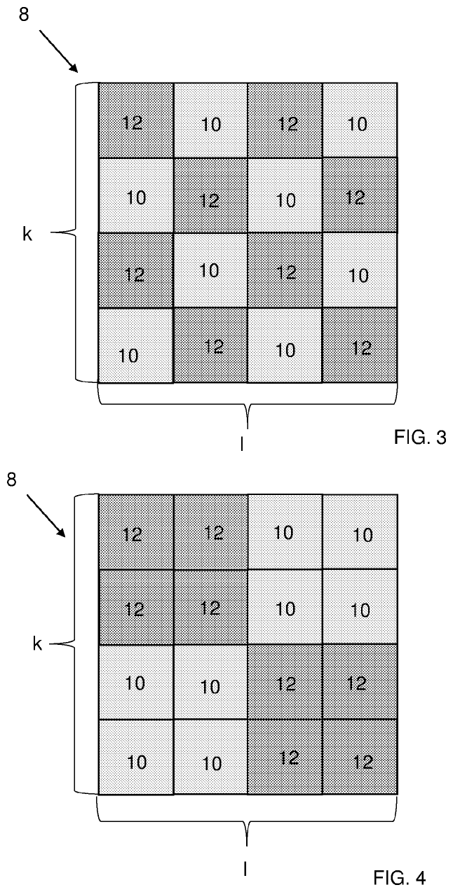

FIG. 3 shows a schematic view of an exemplary optical filter arrangement 8 for use in the imaging system 2 shown in FIG. 1. The arrangement 8 shown in FIG. 3 is similar to that shown in FIG. 1. As such, any features described in relation to FIG. 1 may also apply to the arrangement 8 shown in FIG. 3. Only differences will be described in the following.

In the embodiment shown in FIG. 3, the arrangement 8 comprises no windows 14. In this embodiment, each first filter element 10 is adjacent to one or more second filter elements 12. Expressed differently, the first and second filter elements 10, 12 may be alternately arranged. For example, the first and second filter elements may be arranged to define a chequered pattern. This arrangement may result in a reduced or a least number of image errors, when generating a filtered image, which will be described below.

FIG. 4 shows a schematic view of another exemplary optical filter arrangement 8 for use in the imaging system 2 shown in FIG. 1. The arrangement 8 shown in FIG. 4 is similar to that shown in FIG. 1. As such, any features described in relation to FIG. 1 may also apply to the arrangement 8 shown in FIG. 4. Only differences will be described in the following.

In the embodiment shown in FIG. 4, the arrangement comprises no windows 14. Two or more first filter elements 10 may be arranged adjacent to each other. For example, four first filter elements 10 may be arranged adjacent to each other, e.g. to form a block of first filter elements 10. Two or more second filter elements 12 may be arranged adjacent to each other. For example, four second filter elements 12 may be arranged adjacent to each other, e.g. to form a block of second filter elements. The block of first filter elements 10 may be arranged adjacent to the block of second filter elements 12. A size of the block of first filter elements and/or a size of the block of second filter elements may be selected based on a size or resolution of the array of pixels 6, e.g. to avoid an increase in a number of image errors and/or a decreased of a quality of a filtered image.

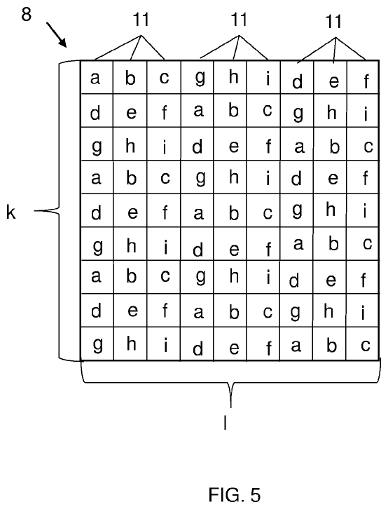

FIG. 5 shows a schematic view of another exemplary optical filter arrangement 8 for use in the imaging system 2 shown in FIG. 1. The arrangement 8 shown in FIG. 5 is similar to that shown in FIG. 1. As such, any features described in relation to FIG. 1 may also apply to the arrangement 8 shown in FIG. 5. Only differences will be described in the following.

In the embodiment shown in FIG. 5, the number of columns I equals nine and the number of rows k equals nine. The arrangement comprises a plurality of filter elements 11a-11i, nine of which are shown in FIG. 5. Each of the filter elements 11a-11i comprises a different transmission wavelength. One of the filter elements 11a-11i may comprise the first filter element 10 and one other of the filter elements 11a-11i may be comprises the second filter element 12.

In the embodiment shown in FIG. 5, the filter elements 11a-11i are arranged to define a mosaic arrangement, such as a quad mosaic arrangement. The exemplary arrangement shown in FIG. 5 may be suitable for use with an imaging sensor having a large array of pixels. This arrangement may result in a reduced or a least number of image errors, when generating a filter image, which will be described below.

It will be appreciated that the arrangement 8 is not limited to the exemplary arrangements disclosed herein. For example, in other arrangements a number of filter elements with different transmission wavelengths and/or a number of windows may be different. Alternatively or additionally, the filter elements and/or the windows may be randomly or semi randomly arranged. This may a reduced number of image errors, when generating a filtered image. For example, a random or semi-random arrangement of the filter elements and/or windows may lead to less interference fringes or interference patterns, such as moiré patterns or fringes. In yet other embodiments, the arrangement may comprise a column and/or row of filter elements having the same transmission wavelength. For example, a number of filter elements with different transmission wavelengths, a number of windows and/or the arrangement of the filter elements and/or windows may be selected based on a selected or desired resolution of image data filtered by the filter elements and/or unfiltered image data.

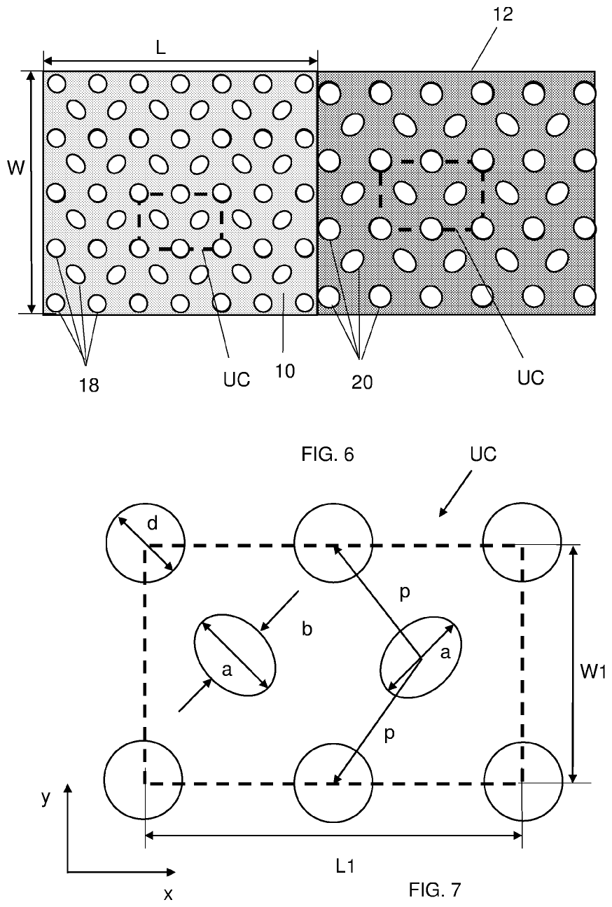

FIG. 6 shows a schematic view of exemplary first and second filter elements for use in the arrangement 8 shown in any one of FIGS. 1 to 5. Each of the filter elements 10, 11a-11i, 12 described above comprises a plurality of nanostructures. The nanostructures of the filter elements 10, 11a-11i, 12 are configured such that each of the filter elements 10, 11a-11i, 12 comprises a different respective transmission wavelength.

By configuring the nanostructures such that the transmission wavelengths, the arrangement 8 may allow for the parallel acquisition of image data associated with at least two different wavelengths. In other words, the arrangement 8 and/or system 2 may allow for multispectral imaging, e.g. using a single imaging sensor. For example, the arrangement 8 and/or system 2 described herein may reduce a number of imaging sensors required for multispectral imaging. Some multispectral imaging systems may comprise multiple imaging sensors, wherein each of the imaging sensors has a respective filter. Each of the multiple imaging sensors may consume power and/or generate electrical noise. As such, a power consumption and/or a generation of electrical noise in the imaging system 2 comprising the arrangement 8 may be reduced compared to multispectral imaging systems comprising the multiple imaging sensors. This in turn may lead to an improved signal to noise ratio. The arrangement 8 may allow for the imaging system 2 to more compact compared to multispectral imaging systems comprising the multiple imaging sensors. Additionally or alternatively, the use of an optical diffraction element, such as a prism, grating or the like, and associated devices may be avoided. This may facilitate the use of the imaging system 2 in devices, systems or apparatuses with limited space, such as vehicles, satellites or the like.

The use of nanostructures may allow for each filter element 10, 11a-11i, 12 to be manufactured with a size or dimension corresponding, e.g. substantially corresponding, to a size or dimension of a respective pixel of the array of pixels 6.

Additionally or alternatively, by providing filter elements comprising nanostructures, the detection of multiples of the different transmission wavelengths may be prevented. This is because, the filter elements 10, 11a-11i, 12 may be configured to allow for resonant coupling of surface plasmon polaritons (SPP) on a surface of the filter elements 10, 11a-11i, 12. Light or radiation incident on the filter elements 10, 11a-11i, 12 may lead to extraordinary optical transmission (EOT), as will be described below. The following description refers to the first and second filter elements 10, 12 shown in FIGS. 1 to 4 above. However, it will be appreciated that any of the features of first and second filter elements 10, 12 described below may also apply to the filter elements 11a-11i shown in FIG. 5.

The first filter element 10 comprises a plurality of first nanostructures 18. The first nanostructures 18 are configured such that the first filter element 10 comprises the first transmission wavelength. Expressed differently, the first nanostructures 18 may be configured such that the first filter element 10 transmits light or radiation having a first wavelength. The terms “first transmission wavelength and “first wavelength” may be interchangeably used.

The second filter element 12 comprises a plurality of second nanostructures 20. The second nanostructures 20 are configured such that the second filter element 12 comprises the second transmission wavelength. Expressed differently, the second nanostructures may be configured such that the second filter element 12 transmits light or radiation having a second wavelength. The terms “second transmission wavelength” and “second wavelength” may be interchangeably used. As described above, the first and second transmission wavelengths are different. For example, at least one of the first and second transmission wavelengths may be larger than at least one other of the first and second transmission wavelengths.

The first and second transmission wavelengths may be between about 0.8 μm and about 7 μm. As such, the arrangement 8 and/or system 2 may allow for the detection of atmospheric gases, e.g. greenhouse gases. For example, the first transmission wavelength may comprise an emission wavelength of methane (CH₄). In this example, the first transmission wavelength is about 1.6 μm. However, it will be appreciated that in other examples, the first transmission wavelengths may be 2.3 μm or 3.3 μm. The second transmission wavelength may comprise an emission wavelength of carbon dioxide (CO₂). In this example, the second transmission wavelength is about 4.2 μm. However, it will be appreciated that in other examples, the second transmission wavelength may be about 1.6 μm, 2 μm or 2.7 μm.

It will be appreciated that the first and/or second transmission wavelengths are not limited to the exemplary values disclosed herein. For example, in other embodiments the first or second transmission wavelength may comprise an emission wavelength of nitric oxide, such as about 1.8 μm, 2.2 μm, 2.7 μm, 2.8 μm, 3.4 μm, 4.5 μm or 5.2 μm. Additionally, it will be appreciated that in other embodiments, only one of the first and second transmission wavelengths may be between about 0.8 μm and about 7 μm.

The arrangement 8 and/or system 2 described herein may have applications other than the detection of atmospheric gases. For example, the arrangement 8 and/or system 2 may allow for the detection of water in soil, the detection of human skin, the detection of fissures or defects in materials, such as plastics materials, the detection of any material that exhibits an optical spectrum in the wavelength range of about 0.8 μm and about 7 μm, the differentiation of ice from water or the like.

In this embodiment, the first and second of nanostructures 18, 20 comprise a plurality of holes. However, it will be appreciated that in other embodiments, the first and/or second nanostructures may be differently implemented. For example, in such other embodiments, the first and/or second nanostructures may be implemented as slits, grooves, and/or projections, such as pillars, pyramids, cones or the like.

Some of the holes have a circular shape and some of the holes have an elliptical shape. However, it will be appreciated that in other embodiments, all the holes may have the same shape and/or at least one or all of the holes may be have a different shape, such as a square, diamond, rectangular, triangular or another polygonal shape.

In some embodiments, the first and second filter elements 10, 12 may each comprise a layer of metal material 19a. The layer of metal material 19a may comprise a metal material, such as copper, aluminium or the like, or a transition metal material, such as gold, silver, chromium or the like. The layer of metal material may comprise a thickness between about 30 nm and 400 nm, preferably 50 nm and 100 nm, such as 80 nm. In such embodiments, the layer of metal material forms a metal-air interface with the air in the environment surrounding the arrangement 8. However, it will be appreciated that in other embodiments, at least one or each of the first and second filter elements may comprise a layer of glass material, such as a chalcogenide glass material. The chalcogenide glass material may comprise germanium-antimony-tellurium (GST) or the like. The chalcogenide glass material may change between an amorphous phase and a crystalline phase, e.g. in response to thermal excitation. When the chalcogenide glass material changes between the amorphous phase and the crystalline phase, a resistivity of the chalcogenide glass material may also change. For example, a resistivity of the chalcogenide glass material may be increased in the amorphous phase relative to the crystalline phase. In the crystalline phase, the chalcogenide glass material may exhibit a metal-like behaviour.

In some embodiments, the first and second filter elements 10, 12 may each comprise the layer of metal material and a layer of dielectric material. The layer of dielectric material may be arranged on the layer of metal material to define a metal-dielectric interface. The layer of dielectric material may comprise an oxide material, such as silicon dioxide, and/or a nitride material, such as a silicon nitride material. The layer of dielectric material may comprise a thickness between 200 nm and 400 nm, such as about 300 nm. The layer of dielectric material may be arranged on the layer of metal material to enhance a transmission of the first and second filter elements 10, 12 and/or as a protective capping layer of the layer of metal material. It will be appreciated that in other embodiments, only one of the first and second filter elements may comprise the layer of dielectric material and/or the layer of dielectric material may be arranged on the layer of glass material of at least one or each of the first and second filter elements.

The first and second filter elements each comprise or define an electromagnetic metasurface. For example, the first nanostructures 18 and second nanostructures 20 are arranged in a periodic arrangement. The first and second nanostructures 18, 20 are formed in the layer of metal material. The periodic arrangement of the first and second nanostructures 18, 20 in the layer of metal material may lead to resonant coupling of SPP on a surface of the layer of metal material. Light or radiation incident on the first and second filter elements 10, 12 may lead to EOT, e.g. due to the resonant coupling of the SPP on the surface of the layer of metal material and constructive interference. Due to permittivity discontinuity at the metal-dielectric or metal-air interface, the SPP have an in-plane momentum. Under normal incident light or radiation, free-space radiation may not be able to couple to the SPP directly. However, the first and second nanostructures 18, 20 may provide additional momentum. For example, the SPP momentum vector is given by:

$${k}_{SPP} = {k}_{si n θ} + {k}_{i , j}$$

where k_{sin θ} is the momentum from light or radiation incident on the first and second filter elements 10, 12 and k_{i,j} is dependent on a diffraction grating order. For normally incident light, k_{sin θ} is zero and K_{SPP} is given by:

$${k}_{SPP} = {k}_{i , j} = \frac{p}{\sqrt{\frac{4}{3} ( \sqrt{{i}^{2} + ij + {j}^{2}} )}} * \sqrt{\frac{{ε}_{m} {ε}_{d}}{{ε}_{m} + {ε}_{d}}} \qquad ( Eq . 1 )$$

where p is the period of the first or second nanostructures 18, 20, i and j are orders of diffraction, εₘ is the permittivity of layer of metal material and ε_{d} is the permittivity of air and/or the layer of dielectric material. The first and second transmission wavelengths are considered to depend from the SPP momentum vector. The coupling of the incident light or radiation with the SPP depends on the period p of the first or second nanostructures 18, 20. As such, the first and second transmission wavelengths may be varied or tuned by varying the period of the first and second nanostructures 18, 20, respectively. This may allow for an increased range of possible wavelengths of the first and second transmission wavelengths of the first and second filter elements 10, 12, respectively.

Additionally, a dimension of each the first nanostructures 18 and each of the second nanostructures 20 in the layer of metal material may aid the resonant coupling of SPP on a surface of the layer of metal material. The dimension of each of the first nanostructures 18 and each of the second nanostructures 20 may correspond to a fraction of the first and second transmission wavelengths, respectively. This may allow for confinement of SPPs in the first and second nanostructures 18, 20. For example, the dimension each of first nanostructures 18 and each of the second nanostructures 20 may be selected as about one fourth of the first and second transmission wavelengths, respectively. The first and second transmission wavelengths may be varied or tuned by varying the dimension each of the first nanostructures 18 and each of the second nanostructures 20, respectively. This may allow for an increased range of possible wavelengths of the first and second transmission wavelengths of the first and second filter elements 10, 12, respectively.

A size of each of the first and second filter elements may correspond to a size of each of the first and second pixel, respectively. For example, each of the first and second filter elements may comprise a length L and a width W, which are shown in FIG. 6 for the first filter element 10 only for sake of clarity. The length L and the width W of each of the first and second filter elements 10, 12 may correspond to a length and width of each of the first and second pixels, respectively.

FIG. 7 shows a schematic view of a unit cell UC of the first and second nanostructures 18, 20 shown in FIG. 6. The terms “unit cell” may be understood as the smallest portion of the arrangement of each of the first and second nanostructures 18, 20 that shows a pattern of the entire arrangement of each of the first and second nanostructures 18, 20. The unit cell UC is indicated in each of the first and second filter elements 10, 12 shown in FIG. 6 by the dashed box. As can be seen in FIG. 7, each unit cell UC comprises six circular holes and two elliptical holes. The circular holes are arranged on a periphery of the unit cell and surround the elliptical holes. The circular holes are arranged to define a rectangular shape of the unit cell UC. However, it will be appreciated that the first and second filter elements 10, 12 are not limited to the arrangement of the first and second nanostructures 18, 20 disclosed herein. For example, in other embodiments, the nanostructures may be arranged in a square lattice arrangement, an aperiodic arrangement and/or the like. Additionally or alternatively, in such other embodiments, the nanostructures may have dissimilar sizes or dimensions.

The period p of the first and second nanostructures 18, 20 is indicated in FIG. 7 and can be understood as a distance to between the centre of elliptical hole and the centre of the circular hole.

Each elliptical hole comprises a first axis a and a second axis b. The first axis a is also referred to a large axis or major axis of the elliptical hole. The second axis b is also referred to a short axis or minor axis of the elliptical hole. The second axis b of each elliptical hole may be selected to correspond to about a quarter of the first or second transmission wavelength. A ratio of the second axis to the first axis, b/a, may be selected to be in a range of about 0.86 to 0.88.

Each hole comprises a diameter d. The diameter may be selected to be approximately the same as the first axis a of each elliptical hole.

In examples where the first transmission wavelength is about 1.6 μm, the second axis b of each elliptical hole of the first nanostructures 18 is about 400 nm and the first axis a is about 454 nm to 465 nm. In such examples, the diameter d of each hole of the first nanostructures 18 is about 454 nm to 465 nm. A period p of the first nanostructures 18 may be about 1.17 μm.

In examples where the second transmission wavelength is about 4.2 μm, the second axis b of each elliptical hole of the second nanostructures 20 is about 1,050 nm and the first axis a is about 1,193 nm to 1,220 nm. In such examples, the diameter d of each hole of the second nanostructures 20 is about 1,193 nm to 1,220 nm. A period p of the second nanostructures 20 may be about 1.17 μm.

It can be seen in FIGS. 5 and 6 that the elliptical holes are arranged at an angle relative to at least a side of the unit cell UC. A first side of the unit cell may comprise or define a length L1 of the unit cell UC. A second side of the unit cell may comprise or define a width W1 of the unit cell UC. The length L1 of the unit cell UC may be considered as extending in the x-direction, as indicated by the coordinate system shown in FIG. 7. The width of the unit cell may be considered as extending in the y-direction, as indicated by the coordinate system shown in FIG. 7. At least one of the elliptical holes may be arranged such that the first axis a of the elliptical hole extends at an angle of about 45° relative to the length L1 of the unit cell UC. At least one other of the elliptical holes may be arranged such that the first axis a of the elliptical hole extends at an angle of about 135°. This arrangement of the elliptical holes may allow for an increased confinement of the SPPs in the first and second nanostructures 18, 20. It will be appreciated that an implementation, size and/or shape of the first and/or second nanostructures may be selected to increase confinement of the SPPs in the first and second nanostructures.

It will be appreciated that each of the filter elements 11a-11i shown in FIG. 5 comprise a respective plurality of nanostructures. The nanostructures of each of the filter elements may be configured such that each filter element 11a-11i comprises a different respective transmission wavelength. For example, a dimension and/or shape of each of the nanostructures of each filter element 11a-11i and/or a period of the nanostructures of each filter element 11a-11i may be selected such that each filter element 11a-11i comprises the different respective transmission wavelength. Any of the features described in relation to the first and second nanostructures may also apply to the nanostructures of each filter element 11a-11i.

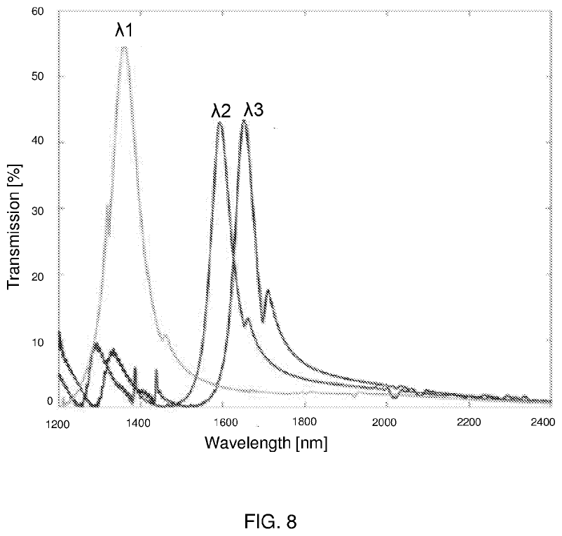

FIG. 8 shows simulated transmission spectra for three exemplary filter elements, one or more of which may be may be used in any of the optical filter arrangements described herein. The transmission spectra shown in FIG. 8 have been simulated for three filter elements comprising an arrangement of nanostructures having the unit cell shown in FIG. 7.

The transmission spectra shown in FIG. 8 have been simulated for a first filter element having a first transmission wavelength λ1, a second filter elements having a second transmission wavelength λ2 and a third filter element having a third transmission wavelength λ3.

The transmission spectra shown in FIG. 8 were simulated using a computer program configured to use a finite difference time domain (FDTD) method. However, it will be appreciated that any computer program configured to solve Maxwell's equations or to perform a rigorous coupled-wave analysis (RCWA) may be used to simulate a transmission spectrum of the filter elements disclosed herein. The transmission spectra shown in FIG. 8 have been simulated for three filter elements each comprising a respective plurality of nanostructures.

The nanostructures of the first, second and third filter elements are arranged and/or shaped in the same manner as the first or second nanostructures 18, 20 shown in FIGS. 6 and 7. However, a dimension of each nanostructure is different for the simulated transmission spectra. For example, each elliptical hole of the first filter element has a first axis a of about 325 nm and a second axis b of about 300 nm. Each circular hole of the first filter element has a diameter d of about 352 nm. A period of the nanostructures of the first filter element is about 0.92 μm. These dimensions and period of the nanostructures of the first filter element result in the first transmission wavelength λ1 being about 1,350 nm.

Each elliptical hole of the second filter element has a first axis a of about 400 nm and a second axis b of about 340 nm. Each circular hole of the second filter element has a diameter d of about 400 nm. A period of the nanostructures of the second filter element is about 1.12 μm. These dimensions and period of the nanostructures of the second filter element result in the second transmission wavelength λ2 being about 1,590 nm.

Each elliptical hole of the third filter element has a first axis a of about 418 nm and a second axis b of about 360 nm. Each circular hole of the third filter element has a diameter d of about 418 nm. A period of the nanostructures of the third filter element is about 1.17 μm. These dimensions and period of the nanostructures of the third filter element result in the second transmission wavelength λ2 being about 1,650 nm.

As such, by varying the size and/or period of the nanostructures of a filter element, the transmission wavelength of the filter element may be varied. For the simulation of the transmission spectra, it was assumed that the nanostructures of each of the first, second and third filter elements are formed in a gold layer having a thickness of 80 nm onto which a 300 nm layer of silicon dioxide is arranged. The relative permittivity of gold and silicon dioxide, which is dependent on a wavelength of the light or radiation that is incident on the first, second and third filter elements, has been obtained from a material library of the computer program. Alternatively, the relative permittivity of gold and silicon dioxide may be determined or simulated based on the refractive index of gold and silicon dioxide, respectively.

For the simulation of the transmission spectra, it was assumed that an angle of incident of the light or radiation relative to a surface of the first, second and third filter elements is about 90°. Additionally, the light or radiation incident on the first, second and third filter elements was simulated as comprising plane waves. However, it will be appreciated that in other embodiments, one or more transmission spectra may be simulated based on angle of incidence of the light or radiation that is different from 90° and/or the light or radiation being focussed, e.g. using an optical device, such as lens, configured to focus the light or radiation onto a surface of one or more filter elements.

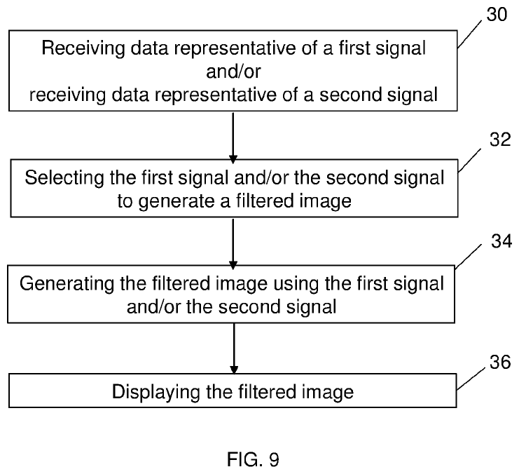

FIG. 9 is a flow chart illustrating in overview a method of generating an image acquired by an imaging system, such as the imaging system 2 described above, according to an embodiment. As described above, the system 2 may comprises the processing device 16. A computer program comprising instructions, which when the program is executed by the processing device 16, cause the processing device 16 to carry out the method, may be stored on the storage medium 16b.

At stage 30, the method comprises receiving data representative of a first signal detected by a pixel. The first pixel may be associated with the first filter element 10 or at least one of the filter elements 11a-11i. The method comprises receiving data representative of a second signal detected by a second pixel. The second pixel may be associated with the second filter element 12 or at least one other of the filter elements 11a-11i. The first and second signals may each be indicative of a photon count or intensity detected by the first and second pixels, respectively.

As mentioned above, the first and second filter elements 10, 12 and/or the filter elements 11a-11i may be arranged to form an array of filter elements, for example as shown in any one of FIGS. 1 to 5.

As such, the first and second signals may be represented as or part of a matrix or array generated for each image frame acquired by the image sensor 4.

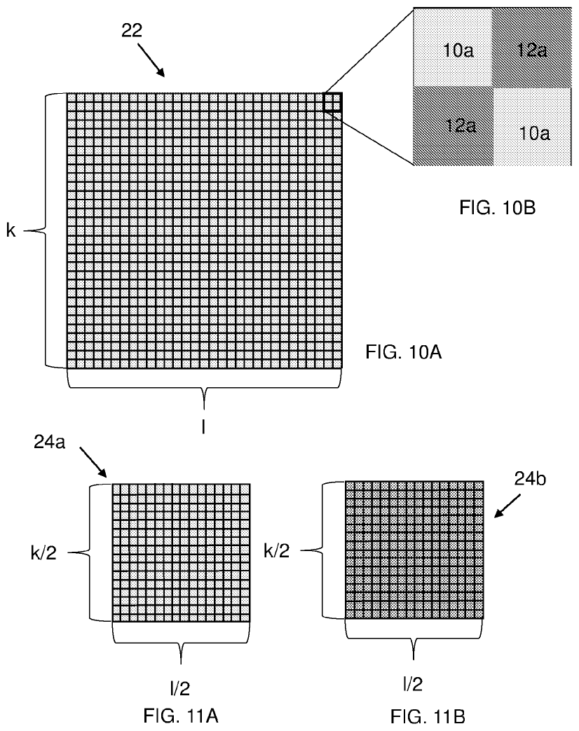

FIG. 10A schematically shows an exemplary matrix or array 22 comprising the first and second signals 10a, 12a for an image frame acquired by the image sensor 4. The matrix or array 22 may comprise k rows and I columns. A size of the matrix or array 22 may be the same as the size of the array of pixels 6.

FIG. 10B shows an enlarged portion of the matrix or array 22 shown in FIG. 10A. The first and second signals 10a, 12a are arranged in the matrix or array 22 in the same manner as the first and second filter elements 10, 12 or the at least one of the filter elements 11a-11i and the at least one other of the filter elements 11a-11i. In this example, an arrangement of the first and second signals 10a, 12a in the matrix or array 22 corresponds to the arrangement 8 of first and second filter elements 10, 12 shown in FIG. 3. However, it will be appreciated that in other embodiments, the first and second signals may be differently arranged.

At stage 32, the method comprises selecting at least one of the first and second signals to generate a filtered image. For example, it may be desirable to generate an image that is filtered by only of the first filter element 10, the second filter element 12, the at least one of the filter elements 11a-11i or the at least one other of the filter elements 11a-11i of the arrangement 8. Alternatively, it may be desirable to generate an image that is filtered by both the first and second filter elements 10, 12 or the at least one of the filter elements 11a-11i and the at least one other of the filter elements 11a-11i of the arrangement 8.

At stage 34, the method comprises generating the filtered image using the selected at least one of the first and second signals 10a, 12a. The selected at least one of the first and second signals 10a, 12a may be represented or provided as a further matrix or array.

FIG. 11A schematically shows an exemplary further matrix or array 24a that has been generated using the first signals 10a of the matrix or array 22 shown in FIG. 10A. FIG. 11B schematically shows an exemplary further matrix or array 24b that has been generated using the second signals 12a of the matrix or array 22 shown in FIG. 10A. It can be seen from FIGS. 11A and 11B that the number of rows and columns of each further matrix or array 24a, 24b is less than the number of rows and columns of the matrix or array 22, e.g. due to the arrangement of the first and second filter elements 10, 12. In this example, each of the further matrix or array 24 comprise k/2 rows and l/2 columns.

At stage 36, the method comprises displaying the further matrix or array 24 as a filtered image, for example on the display screen 17.

The system 2 and/or method may allow for so-called “post-processing” of the array of pixels 6 of the image sensor 4. For example, as described above, only an image based on the pixels of the array of pixels 6 associated with either the first or second filter elements 10, 12 or any of the filter elements 11a-11i may be generated and/or displayed.

Additionally, as described above, the arrangement 8 of the first and second filter elements 10, 12 and/or the filter elements 11a-11i may be selected such that a number of first filter elements 10 is different relative to a number of second filter elements 12 or a number of the at least one of the filter elements 11a-11i is different relative to a number of the at least one other of the filter elements 11a-11 This may result in a different resolution of an image that has been generated using the first signals 10a relative to a resolution of an image that has been generated using the second signals 12a.

As described above, in some embodiments, the arrangement 8 additionally comprises the windows 14. In such embodiments, the processing device 16 may be configured to generate an unfiltered image using a third signal detected by the third pixel.

For example, the method may comprise receiving data representative of a third signal detected by the third pixel or another pixel that is configured to detect unfiltered light or radiation. For example, the other pixel may not be covered by the arrangement 8. For example, in some embodiments, the size of the array of filter elements may be less than the size of the array of pixels. This may result in one or more pixels of the array of pixels that are not covered by the arrangement.

The third signal may be indicative of a photon count or intensity detected by the third pixel or the other pixel. The third signal may be represented as or part of a matrix or array generated for each image frame acquired by the image sensor 4. For example, the first, second and third signals may be arranged in the matrix or array in the same manner as the first and second filter elements 10, 12 and the windows 14, e.g. as shown in FIG. 1.

The method may comprise selecting the third signal to generate the unfiltered image. The method may comprise generating the unfiltered image using the third signals. The third signals may be represented or provided as the further matrix or array. The method may comprise displaying the further matrix or array as the unfiltered image, e.g. on the display screen. As such, by configuring the arrangement 8 to comprise the windows 14 or to be smaller than the array of pixels 6, it may be possible to generate an unfiltered image in addition or to the filtered image.

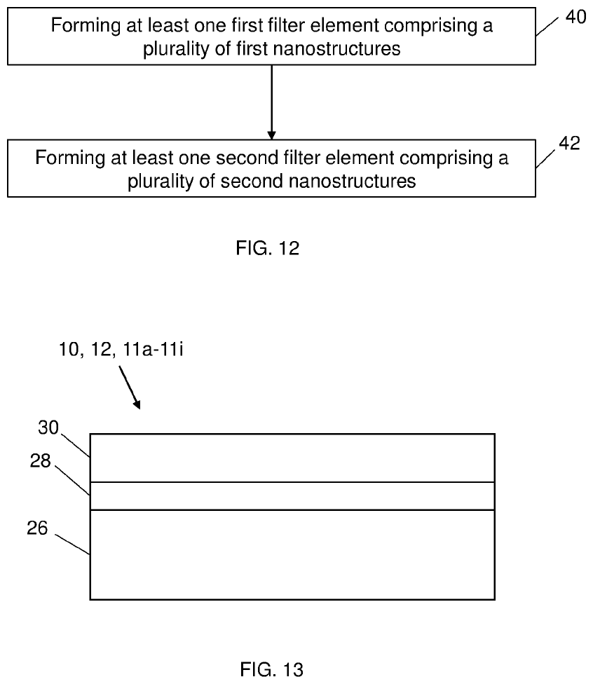

FIG. 12 is a flow chart illustrating in overview a method of manufacturing an optical filter arrangement according to an embodiment.

At stage 40, the method comprises forming a first filter element 10 comprising a plurality of first nanostructures 18.

At stage 42, the method comprises forming a second filter element 12 comprising a plurality of second nanostructures 20. Although FIG. 12 shows stages 40 and 42 separately, it will be appreciated that the first and second filter elements 10, 12 may be simultaneously formed.

The method may comprise using a lift-off process or the like to form the first and second filter elements 10, 12. This may facilitate manufacturing of the arrangement, which in turn may result in a reduced manufacturing time and/or reduced manufacturing costs.

For example, a layer of resist may be deposited on a substrate, e.g. using a coating or spin coating process. The layer of resist may comprise a plastic material, such as Poly (methyl methacrylate) (PMMA). The substrate may comprise a glass material, such as borosilicate glass. Prior to depositing the resist, an interlayer may be deposited on the substrate. The interlayer may comprise a polymer material, such as polydimethylglutarimide (PMGI), and/or a lift-off resist (LOR) layer.

The method may comprise applying a pattern to the layer of resist, e.g. using a lithographic process, such as electron beam lithography or deep ultraviolet photolithography. The pattern may be applied to the layer of resist in a single lithographic process step. The pattern may be an inverse pattern of the first and second filter elements, comprising the first and second nanostructures, respective, to be formed. By using a single lithographic process step to apply the pattern to the layer of resist, manufacturing of the arrangement may be facilitated. This in turn may result in a reduced manufacturing time and/or reduced manufacturing costs.

The method may comprise depositing a layer of metal material on the patterned layer of resist, e.g. using an evaporation process, such as an electron beam evaporation process. Alternatively or additionally, the method may comprise depositing a layer of glass material on the patterned resist, e.g. using a deposition process, such as thermal evaporation, sputtering or the like.

The method may comprise removing the layer of resist and the layer of metal material deposited thereon. This may result in a patterned layer of metal material on the substrate, e.g. thereby forming the first and second filter elements. Alternatively or additionally, the method may comprise removing the layer of resist and the layer of glass material deposited thereon. This may result in a patterned layer of glass material on the substrate, e.g. thereby forming the first and second filter elements. It will be appreciated that in some embodiments, at least one of the first and second filter elements may comprise the layer of metal material and at least one other of the first and second filter elements may comprise the layer of glass material.

In some embodiments, the method may comprise depositing a layer of dielectric material on patterned layer of metal material or the patterned layer of glass material, using a deposition process such as plasma enhanced chemical vapour deposition (PECVD) process. It will be appreciated that at least one or each of the first and second filter elements may comprise the layer of dielectric material.

It will be appreciated that the windows may be formed in a similar manner as the first and second filter elements. In such embodiments, the pattern applied to the layer of resist may be an inverse pattern of the first and second filter elements and the windows to be formed.

It will be appreciated that the method may comprise one or more additional steps, such as an annealing step of the patterned layer of metal or the patterned layer of glass material on the substrate.

It will be appreciated that any of the filter elements 11a-11i may be formed in the same manner as the first and/or second filter elements.

FIG. 13 shows a schematic cross-sectional view of a filter element for use in the optical filter arrangement 8 of any one of FIGS. 1 to 5. The filter element shown in FIG. 13 may comprise the first filter element 10, the second filter element 12 or any one of the filter elements 11a-11i. The filter element shown in FIG. 13 may be manufactured using the method described in relation to FIG. 12.

As can be seen in FIG. 13, the filter element may comprise a substrate 26. The filter element may comprise a layer of metal material 28. The layer of metal material 28 is arranged on the substrate 26. The nanostructures, e.g. the first nanostructures, the second nanostructures or the nanostructures of any one of the filter elements 11a-11i, (not shown in FIG. 13) are formed in the layer of metal material 28. The filter element may comprise a layer of dielectric material 30. The layer of dielectric material 30 is arranged on the layer of metal material 28. The substrate 26, the layer of metal material 28 and the dielectric layer 30 shown in FIG. 13 may comprise any of the features of the substrate, the layer of metal material and/or the layer of dielectric material described above. It will be appreciated that in some embodiments, no layer of dielectric material may be arranged on the layer of metal material. Although FIG. 13 shows the filter element as comprising the layer of metal material 28, it will be appreciated that in other embodiments, the filter element may comprise a layer of glass material, as described above, instead or in addition the layer of metal material.

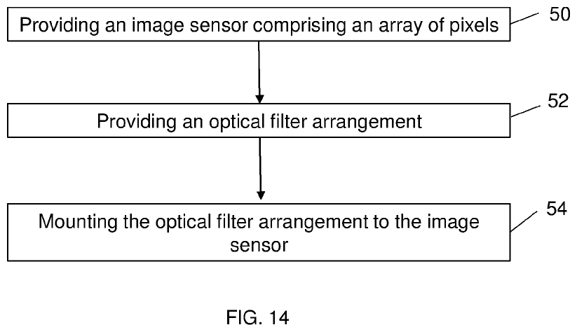

FIG. 14 is a flow chart illustrating in overview a method of manufacturing an imaging system according to an embodiment.

At stage 50, the method comprises providing an image sensor comprising an array of pixels, such as the image sensor 4 described above.

At stage 52, the method comprises providing an optical filter arrangement, such as any of the optical filter arrangements 8 described above.

At stage 54, the method comprises mounting the optical filter arrangement to the image sensor such that the first filter element is associated with a first pixel of the array of pixels and the second filter element is associated with a second pixel of the array of pixels.

For example, the method may comprise using a flip-chip process to manufacture the imaging system. For example, the image sensor may be aligned relative to the optical filter arrangement. The image sensor may be mounted to the optical filter arrangement, e.g. using an adhesive, such as an adhesive that is at least transparent in the infrared spectrum. The adhesive may comprise a light or radiation curable adhesive, such as an ultraviolet curable adhesive. Subsequently, the image sensor and optical filter arrangement mounted thereto may be flipped such that the optical filter arrangement is arranged on top of the image sensor.

Although the processing device 16 is described as being local to or part of the image sensor 4, it will be appreciated that in other embodiments, the processing device may be separately and/or remotely provided from the image sensor. For example, in such other embodiments, the processing device may be part of a computer system, which may include a personal computer, a laptop computer, a tablet computer, a mobile phone, a smartphone, PDA and/or the like.

In such other embodiments, the processing device may comprise a processor, which may be provided in the form of a central processing unit (CPU), maths co-processor (MCP), graphics processing unit (GPU), and/or the like. The processor may be a single core or multicore processor. The processing device may comprise memory and/or other data storage, which may be implemented on DRAM (dynamic random access memory), SSD (solid state drive), HDD (hard disk drive) or other suitable magnetic, optical and/or electronic memory device. The processor and/or the memory and/or data storage may be arranged locally, e.g. provided in a single device or in multiple devices in in communication at a single location or may be distributed over several local and/or remote devices. The processing device may comprise a communications module, e.g. a wireless and/or wired communications module. The communications module may be configured to communicate over a cellular communications network, Wi-Fi, Bluetooth, ZigBee, near field communications (NFC), IR, satellite communications, other internet enabling networks and/or the like. The communications module may be configured to communicate via Ethernet or other wired network or connections, via a telecommunications network such as a POTS, PSTN, DSL, ADSL, optical carrier line, and/or ISDN link or network and/or the like, via the cloud and/or via the internet, or other suitable data carrying network. The communications module may be configured to communicate via optical communications such as optical wireless communications (OWC), optical free space communications or Li-Fi or via optical fibres and/or the like. The processing device may be configured to communicate with the image sensor via the communications module.

The display screen may be part of the computer system. The computer system may comprise an input device or devices, such as a computer keyboard, a mouse, a trackball or the like, by which the user can provide input to the computer system. Other kinds of devices can be used, for example, feedback provided to the user can be any form of sensory feedback, e.g., visual feedback, auditory feedback, or tactile feedback; and input from the user can be received in any form, including acoustic, speech, or tactile input. In such other embodiment, the image sensor may comprise another processing device configured to transmit the first, second and/or third signals to the processing device. The other processing device may be the same or similar to the processing device 16 described above.

It will be appreciated that the term “size” may be interchangeably used with the term “dimension.”

It will be appreciated that the term “acquired” may be interchangeably used with any of the terms “obtained,” “recorded” or “captured.”

It will be understood that references to a plurality of features may be interchangeably used with references to singular forms of those features, such as for example “at least one” and/or “each”. Singular forms of a feature, such as for example “at least one” or “each,” may be used interchangeably.

Although the disclosure has been described in terms of embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1. An optical filter arrangement for use with an image sensor, the arrangement comprising:
at least one first filter element comprising a plurality of first nanostructures; and
at least one second filter element comprising a plurality of second nanostructures; wherein the plurality of first nanostructures is configured such that the at least one first filter element comprises a first transmission wavelength and the plurality of second nanostructures is configured such that the at least one second filter element comprises a second transmission wavelength that is different from the first transmission wavelength.

2. The arrangement of claim 1, wherein the first and/or second transmission wavelengths are between about 0.8 μm and about 7 μm.

3. The arrangement of claim 1, wherein the at least one first element and the at least one second filter element are arranged to form an array of filter elements.

4. The arrangement of claim 1, wherein at least one or each of the at least one first filter element and the at least one second filter element comprises a layer of metal material or a layer of glass material, the plurality of first nanostructures and the plurality of second nanostructures being formed in the layer of metal material or the layer of glass material of the at least one or each of the at least one first filter element and the at least one second filter element.

5. The arrangement of claim 4, wherein the layer of metal material comprises at least one of: gold, silver, chromium, copper and aluminium or the layer of glass material comprises a chalcogenide glass material.

6. The arrangement of claim 1, wherein at least one or each of the plurality of first and second of nanostructures comprises a plurality of holes, a plurality of slits, a plurality of grooves and/or a plurality of protrusions.

7. The arrangement of claim 1, wherein the plurality of first and/or second nanostructures are arranged in a periodic arrangement.

8. The arrangement of claim 1, wherein the first transmission wavelength depends on a dimension of each of the plurality of first nanostructures and/or a periodicity of the plurality of first nanostructures.

9. The arrangement of claim 8, wherein the second transmission wavelength depends on a dimension of each of the plurality of second nanostructures and/or a periodicity of the plurality of second nanostructures.

10. The arrangement of claim 1, wherein the at least one first filter element and the at least one second filter element each comprise or define an electromagnetic metasurface.

11. The arrangement of claim 1, wherein the arrangement comprises at least one window or opening and wherein at least one of:
the at least one window or opening is arranged adjacent at least one of: the at least one first filter element and the at least one second filter element;
the at least one first filter element, the at least one second filter element and/or the at least one window or opening are alternately arranged;
the at least one first filter element, the at least one second filter element and/or the at least one window are arranged to form a mosaic arrangement, a random arrangement or a semi random arrangement.

12. A method of generating an image acquired by an imaging system, the imaging system comprising:
an image sensor comprising an array of pixels; and
an optical filter arrangement according to claim 1, wherein the at least one first filter element is associated with at least one first pixel of the array of pixels and the at least one second filter element is associated with at least one second pixel of the array of pixels, the method comprising:
receiving data representative of a first signal detected by the at least one first pixel;
receiving data representative a second signal detected by the at least one second pixel;
selecting at least one of the first signal and the second signal to generate the image;
generating the image using the selected at least one of the first signal and the second signal.

13. The method of claim 12, wherein the at least one window or opening is associated with at least one third pixel of the array of pixels or the array of pixels comprises another pixel that is configured to detect unfiltered light or radiation, the method comprising:
receiving data representative of a third signal detected by the at least one third pixel or the other pixel;
selecting the third signal to generate an unfiltered image;
generating the unfiltered image using the third signa.

14. An imaging system comprising:
an image sensor comprising an array of pixels; and
an optical filter arrangement according to claim 1, wherein the at least one first filter element is associated with at least one first pixel of the array of pixels and the at least one second filter element is associated with at least one second pixel of the array of pixels.

15. The system of claim 14, wherein the optical filter arrangement is arranged relative to the array of pixels such that light or radiation detected by the image sensor passes through the at least one first filter element and/or the at least one second filter element before being incident on the at least one first pixel of the array of pixels and/or the at least one second pixel of the array of pixels, respectively.

16. The system of claim 14, wherein the at least one window or opening is associated with at least one third pixel of the array of pixels.

17. The system of claim 14, wherein the system comprises a processing device configured to carry out the method according to claim 12.

18. A computer program comprising instructions which, when the program is executed by a processing device, cause the processing device to carry out the method according to claim 12.

19. A method of manufacturing an optical filter arrangement for use with an image sensor, the method comprising:
forming at least one first filter element comprising a plurality of first nanostructures; and
forming at least one second filter element comprising a plurality of second nanostructures; wherein the plurality of first nanostructures is configured such that the at least one first filter element comprises a first transmission wavelength and the plurality of second nanostructures is configured such that the at least one second filter element comprises a second transmission wavelength that is different from the first transmission wavelength.

20. A method of manufacturing an imaging system, the method comprising:
providing an image sensor comprising an array of pixels; and
providing an optical filter arrangement according to claim 1; and
mounting the optical filter arrangement to the image sensor such that the at least one first filter element is associated with at least one first pixel of the array of pixels and the at least one second filter element is associated with at least one second pixel of the array of pixels.
